(19) United States
(12) Patent Application Publication
(10) Pub. No.: US 2018/0346372 A1
(43) Pub. Date: Dec. 6, 2018

(54) MICROWAVE PROCESSING OF THERMOELECTRIC MATERIALS AND USE OF GLASS INCLUSIONS FOR IMPROVING THE MECHANICAL AND THERMOELECTRIC PROPERTIES

(71) Applicant: The Board of Regents for Oklahoma State University, Stillwater, OK (US)

(72) Inventors: DARYOOSH VASHAEE, Cary, NC (US); AMIN NOZARIASBMARZ, State College, PA (US); LOBAT TAYEBI, Milwaukee, WI (US); JERZY S. KRASINSKI, Stillwater, OK (US)

(21) Appl. No.: 15/778,704

(22) PCT Filed: Nov. 30, 2016
(86) PCT No.: PCT/US2016/064292

§ 371 Date: May 24, 2018

Related U.S. Application Data
(60) Provisional application No. 62/260,829, filed on Nov. 30, 2015.

(51) Int. Cl. C03C 14/00; C03C 10/00; C03C 3/076; C03C 3/32; H01L 35/22; C03C 12/00

(52) U.S. Cl. CPC C03C 14/004; C03C 10/00; C03C 12/00; C03C 3/321; H01L 35/22; C03C 3/076

(57) ABSTRACT

According to an embodiment, there is provided a method of creating amorphous and amorphous-crystalline materials using microwave energy in the form of standing waves. The relatively quick processing time of the method allows investigating and creating a large number of material structures with various dimensions. An embodiment utilizes a scalable technique to produce high efficiency bulk thermoelectric structures as well as thin and thick.

### CROSS REFERENCE TO RELATED APPLICATIONS

This application claims the benefit of U.S. Provisional Patent Application Ser. No. 62/260,829 filed on Nov. 30, 2015, and PCT co-pending application No. PCT/US2016/064292, filed Nov. 30, 2016, and incorporates said applications by reference into this document as if fully set out at this point.

### STATEMENT REGARDING FEDERAL SPONSORED RESEARCH OR DEVELOPMENT

This invention was made with U.S. Government support under NSF Grant No. CBET-0933763 awarded by the National Science Foundation. The Government has certain rights in this invention.

### TECHNICAL FIELD

This disclosure relates to systems and methods of forming polycrystalline, amorphous, and mixed phase of amorphous, heterogeneous and polycrystalline composite materials using microwave energy.

### BACKGROUND

Amorphous phases can possess fundamentally different electrical and thermal properties than crystalline or nano-crystalline forms of the thermoelectric (TE) materials. There has been only limited work on bulk amorphous electronic materials, and even less on their TE properties. This is mainly due to the challenges in making large size bulk amorphous materials, which has discouraged their large scale applications. The interfaces in amorphous materials introduce sites for scattering of charge carriers and phonons, which is the major concern in energy materials, such as TEs.

In general, in nanostructured materials the boundaries form the predominant resistance to electrical and thermal energy transport. They not only cause electron and phonon scattering resulting in electrical and thermal resistance, but also break any long-range periodicity of the materials comprising the interfaces. Moreover, the interfacial region in a nanostructured material can be itself amorphous. In fully amorphous materials the interfaces do not exist and both short and long range periodicities are lost.

If the density of point defects in a crystalline material becomes very high, the material undergoes a phase transition to an amorphous state where neither long range nor short range order of the atoms can be found. Amorphous materials can possess quite different electrical and thermal properties than their crystalline form. For example, instead of bands and gaps, extended and localized states are distinguishable in their quasi-continuous energy spectrum. Localization of electronic states can happen at certain sites or in certain regions of the amorphous material. As more band states are localized, the disorderness raises and most likely the localized states will be close to the band edges. In the case of semiconductors, the fluctuations in short-range order (bond lengths and angles) lead to band tails extending into the energy gap. Interestingly, the band tails from the valence and conduction bands may overlap. Localized wave functions cannot be expanded as a plane wave. In contrast to crystalline materials in which the localized states appear in the form of Dirac delta function discrete energy levels, the states in the amorphous materials fill the energy spectrum continuously. Moreover, there are some energy levels in amorphous materials which separate the extended states from the localized ones and are called mobility edges.

When the lattice thermal conductivity becomes comparable to (or smaller than) the electronic thermal conductivity, the enhancement in the TE dimensionless figure-of-merit (ZT), a measure of TE efficiency, becomes less significant.

The figure of merit in fine grained thermoelectric materials has been studied and the condition under which a fine-grained material has enhanced figure of merit is known. Although fine grained TE materials have been investigated vastly in the past, there have been only limited reports on the development of amorphous based TE structures.

The amorphous-crystalline composite structure offers several additional degrees of freedom for controlling the material properties. For example, with the control of the volume fraction of the amorphous phase, one can modify the electrical and thermal properties. It can simultaneously reduce the thermal conductivity and increase the TE power factor. This is possible if the crystallite sizes are smaller than the energy relaxation length of the charge carriers, larger than the mean free path of the charge carriers, and smaller than the mean free path of the phonons. The first condition is of special importance, as it requires crystallite sizes of smaller than a few ten nanometers in most good TE materials.

Microwave energy has been widely used to synthesize and sinter different class of materials; however, it has not demonstrated improvement of the thermoelectric properties through in-situ decrystallization of the material in the microwave oven or cavity.

What is needed is a new way of creating a new state of amorphous and amorphous-crystalline materials using microwave energy. Further, a method is needed that is scalable to produce high efficiency bulk TE structures as well as thin and thick films. The method might further enable control over the volume of the amorphous domains in a crystalline TE material. Finally, a method is needed that enables control over the density and porosity of the TE material.

Before proceeding to a description of the present invention, however, it should be noted and remembered that the description of the invention which follows, together with the accompanying drawings, should not be construed as limiting the invention to the examples (or embodiments) shown and described. This is so because those skilled in the art to which the invention pertains will be able to devise other forms of this invention within the ambit of the appended claims.

### SUMMARY OF THE INVENTION

According to an embodiment, in order to further improve the ZT, one has to increase the power factor simultaneously while reducing the thermal conductivity. The new material structures based on mixture of amorphous and polycrystalline phases, namely amorphous-crystalline composites, result in significant enhancement of the TE power factor, which can be along with the reduction of the thermal conductivity, compared with the single crystalline, polycrystalline, or nano-crystalline form of the same constituent materials.

As such, herein is disclosed a method to create a new state of amorphous and amorphous-crystalline TE materials using microwave energy. The quick processing time of the invented method allows investigating and creating a large number of material structures with various dimensions. The present method proposed a scalable technique to produce high efficiency bulk TE structures as well as thin and thick films.

An embodiment opens a new roadmap for the discovery of new high efficiency TE material structures. The method is applicable to any TE material that can absorb microwave energy. The absorption can be either through the electric field or the magnetic field of the microwave field. The microwave frequency can vary from 300 MHz to 300 GHz. The microwave field-material interaction can create non-equilibrium phases such as metastable or amorphous phases in the material structure. Creation of such material phases can enhance the TE performance, in particular, the TE dimensionless figure-of-merit (ZT), in comparison to the materials prepared with prevalent sintering methods. The method for creation of such material structures opens a new landscape for discovering high performance TE structures as well as novel electronic materials.

Materials such as glass powder can be mixed with thermoelectric powders prior to consolidation to improve their mechanical properties of the consolidated thermoelectric material against mechanical and/or thermal shocks and thermal cycling. This approach is referred to as glass inclusion in the TE material. The glass inclusion method is applicable to most thermoelectric materials, e.g., bulk Bi₂₋₂ₓSb₂ₓTe₃ (x=0.66 to 0.84), and Bi₂Sₑ₃ₓTe₃₋₃ₓ (x=0 to 0.34), magnesium silicide (Mg₂Si), higher manganese silicide (MnSi₁₊ₙ, n=0.73 to 0.75), and silicon germanium (Si₁₋ₓGeₓ, x=0 to 1) based materials. The glass inclusion method is also applicable to materials processed with microwave energy, or other sintering techniques such as hot press, spark plasma sintering, plasma pressure compaction, etc.

According to an embodiment, there is provided a method of producing an amorphous or amorphous-crystalline material, comprising the steps of: obtaining a quantity of a thermoelectric material; configuring a microwave cavity to produce a standing wave when radiated by microwave radiation; activating a microwave generator to produce said microwave radiation and said standing wave; exposing the thermoelectric material to said standing wave for a length of time at least long enough to produce said amorphous or amorphous-crystalize material.

In some embodiments, the thermoelectric material will be selected from the group consisting of Bi₂₋₂ₓSb₂ₓ, Te₃ (x=0.66 to 0.84), Bi₂Se₃ₓTe₃₋₃ₓ (x=0.66 to 0.84), magnesium silicide (Mg₂Si), higher manganese silicide (MnSi₁₊ₙ, n=0.73 to 0.75), silicon, silicon germanium (Si₁₋ₓGeₓ, x=0 to 1), iron silicide (FeSi₂), copper silicide, half-Heusler alloys, Skutterudites, clathrates, zintl phases, PbTe, zinc antimonide, oxide thermoelectrics, and organic thermoelectrics.

In another embodiment, there is provided a device for creating an amorphous or amorphous-crystalline material from a thermoelectric material, comprising: a microwave generator operable to produce a microwave signal; a reflective partition, said reflective partition configured to reflect at least a portion of said microwave signal back toward said microwave generator; a microwave cavity situated between said microwave generator and said reflective partition; a sample container within said microwave cavity, said sample container configurable to house said thermoelectric material; an isolator situated between said microwave cavity and said microwave generator; and, a tuner situated between said isolator and said generator, said tuner adaptable to match a load created by said sample container to said microwave signal, said tuner and said partition operable together to creating a standing wave signal within said microwave cavity when said microwave generator is operating.

In another variation, there is provided a method of producing a heterogeneous phase material, comprising the steps of: obtaining a quantity of a thermoelectric material; configuring a microwave cavity to produce a standing wave when radiated by microwave radiation; activating a microwave generator to produce said microwave radiation and said standing wave; exposing the thermoelectric material to said standing wave for a length of time at least long enough to produce said heterogeneous phase material.

The foregoing has outlined in broad terms some of the more important features of the invention disclosed herein so that the detailed description that follows may be more clearly understood, and so that the contribution of the instant inventors to the art may be better appreciated. The instant invention is not to be limited in its application to the details of the construction and to the arrangements of the components set forth in the following description or illustrated in the drawings. Rather, the invention is capable of other embodiments and of being practiced and carried out in various other ways not specifically enumerated herein. Finally, it should be understood that the phraseology and terminology employed herein are for the purpose of description and should not be regarded as limiting, unless the specification specifically so limits the invention.

### BRIEF DESCRIPTION OF THE DRAWINGS

These and further aspects of the invention are described in detail in the following examples and accompanying drawings.

FIG. 1 contains a schematic illustration of a microwave system with different applicator configurations: FIG. 1A illustrates a material under pressure, FIG. 1B illustrates a static material, and FIG. 1C illustrates a moving rod embodiment. A schematic of the electric field standing wave signal inside the cavity is shown in FIG. 1D. An exemplary top view of the electric field distribution is shown inside the cavity in FIG. 1E. The sample is placed in one of the locations where the electric field is maximum in the cavity.

FIG. 2 contains exemplary schematic diagrams of randomly orientated grains mixed with amorphous domains (FIG. 2A), preferentially orientated grains mixed with amorphous domains (FIG. 2B), crystalline grains (preferentially or randomly oriented) in amorphous host (FIG. 2C), and amorphous domains in crystalline or (poly-crystalline) host (FIG. 2D).

FIG. 3 contains plots of the thermoelectric properties of microwave processed SiGeB-Glass amorphous-crystalline composites according to an embodiment.

FIG. 4 contains a comparison of XRD patterns for different microwave processed samples (FIG. 4A) and a comparison of the highest intensity XRD lines in samples MW200-5 and MW320-5 (FIG. 4B) for an embodiment.

FIG. 5 contains comparisons of thermal diffusivity (FIG. 5A), and thermal conductivity of different (Biₓ,Sb₁₋ₓ)₂Te₃ samples (FIG. 5B) for an embodiment.

FIG. 6 contains an example of the effect of microwave process temperature on decrystallization of Bi₂Te₃ powder.

FIG. 7 contains exemplary high resolution TEM images of Bi₂Te₃ as-prepared powder (FIG. 7A), and microwave processed at 400° C. (FIG. 7B). The microwave processed sample shows amorphous-crystalline composite structure.

FIG. 8 contains a comparison of the thermoelectric properties of p-type (Bi₂Te₃)₁(Sb₂Te₃)₅ sample after hot press (circles) and after microwave processing (diamond).

FIG. 9 contains microwave processed thermoelectric legs cut and packaged into a device for use with an embodiment.

FIG. 10 contains a comparison between the generated power from body heat using the microwave processed and a commercial thermoelectric device. The microwave processed device resulted in 4 to 7 times more power than a commercial thermoelectric device under different air flow conditions. The device generated continuous 44 μW/cm² on wrist without any airflow and 156 μW/cm² with airflow and without a heat-sink.

FIG. 11 contains comparison of the thermal conductivity of different p-type BiSbTe alloys obtained from microwave processing.

FIG. 12 contains comparisons of the thermoelectric properties of p-type (Bi₂Te₃)₁(Sb₂Te₃)₃ samples with 40% (star) and 50% (diamond) porosity prepared by microwave processing for an embodiment.

FIG. 13 contains an example the effect of microwave processing on n-type hot-pressed BiSeTe samples.

FIG. 14 contains an exemplary TEM image demonstrating the grain structure of microwave processed BiSeTe sample, (FIG. 14A), a higher magnification image highlighting the disordered regions present within the grains, (FIG. 14B), and atomic resolution image of a disordered/amorphous region within a grain (FIG. 14C).

FIG. 15 contains a schematic illustration of a microwave system suitable for use with an embodiment.

### DETAILED DESCRIPTION

While this invention is susceptible of embodiment in many different forms, there is shown in the drawings, and will herein be described hereinafter in detail, some specific embodiments of the instant invention. It should be understood, however, that the present disclosure is to be considered an exemplification of the principles of the invention and is not intended to limit the invention to the specific embodiments or algorithms so described.

By way of overview, an embodiment opens a new roadmap for the development of new high efficiency TE material structures as well as development of amorphous-crystalline composite materials with unique thermal and electrical properties. The material can be fully amorphous or nano-crystalline with crystallite sizes as small as 1 nm and as large as the size of the sample. Various embodiments of the process can be applied to thin films, thick films, and bulk materials. The material size can be arbitrarily small, large limited to the size of the microwave radiation environment, or long travelling through the microwave radiation chamber. The microwave environment can be a single mode or multimode microwave cavity with standing waves. The microwave energy can be fully or partially coupled to the material which acts as the load.

The microwave coupling to the material can be controlled with an impedance matching apparatus, such as three-stub tuner or E-H tuner, and/or with waveguide sliding shorts (i.e., the plunger in FIG. 15). The sling short (plunger) can be used to tune the length of the cavity so that a standing wave voltage is formed inside of it. The voltage standing wave ratio (VSWR) can be from one to infinity; however, the closer the VSWR is to one, the stronger is the field, hence the stronger is the field induced decrystallization. In practice it is preferable that the VSWR be less than 2 and as close to 1 as possible, although other values might be useful in particular instances depending on the values chosen for the other parameters.

Turning to the example of FIG. 15 in greater detail, there is a microwave generator which is used to provide microwave energy to a microwave cavity which contains the sample.

The plunger of FIG. 15 is movable in this embodiment and can be positioned so as to create a standing wave in the microwave cavity after the microwave generator is activated. Its surface is designed to at least partially reflect the microwave energy provided by the generator back toward the sample. Of course, a static partition could be used instead of the movable piston if, for example, large numbers of materials of the same type are to be sequentially processed.

Next to the generator is an isolator which functions to block the returning microwave energy that is reflected from the face of the plunger. This component serves to protect the source from damage when the microwave generator is operational.

Adjacent to the isolator in FIG. 15 is a tuner. In this embodiment, the tuner is used for impedance matching the load (here, the specimen) to the source so that the maximum energy is transferred into the material. As such, the tuner and plunger work cooperatively to create standing waves from the microwave generator/source.

In some embodiments, the time required to produce the amorphous or amorphous-crystalline material will vary and may need to be determined on a trial-and-error basis which might be different for each TE material. In practice, the time can vary from several seconds to several minutes depending on process parameters such as the microwave power, the VSWR, and the material. For some materials it may take longer, but it is usually less than 60 minutes, but could be as long as a few hours. The optimum time is can be found by radiating several similar materials at different time intervals and characterize them after MW radiation.

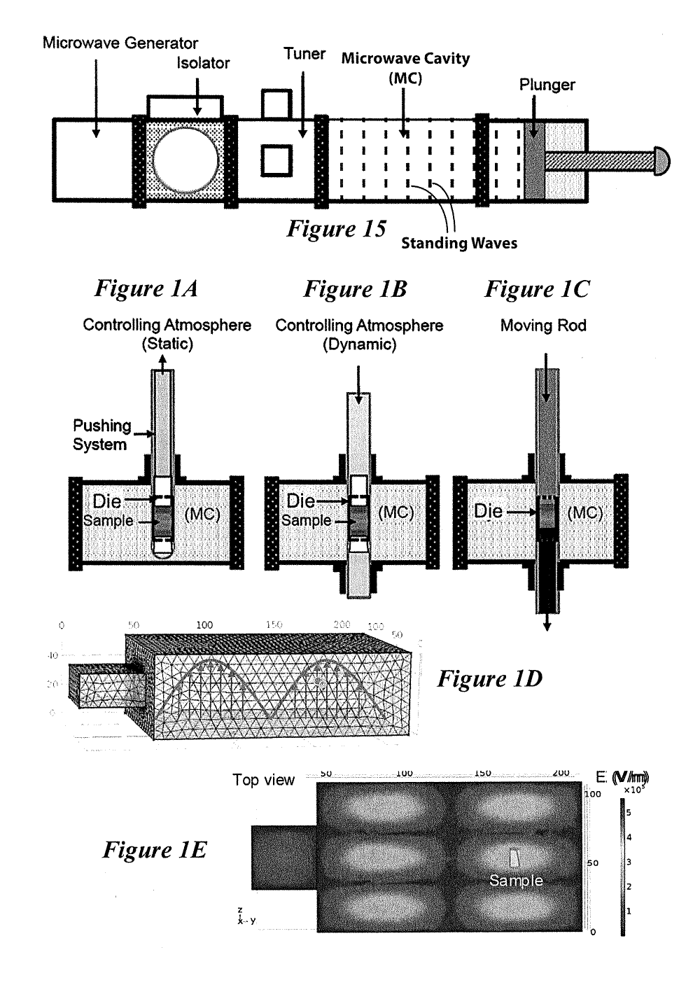

The cavity excites the desired mode of the MW field. FIGS. 1D and 1E show the schematic finite element model and the resulted E field inside a cavity. In this example, the cavity is excited through a smaller waveguide on the left, which delivers the power from the microwave launcher. TE302 mode is observed in the cavity.

In this example, the polarized E field of the microwave interacts with the atomic bond and breaks the lattice bonds which leads to its decrystallization.

By controlling the microwave power, duty cycle, radiation time, temperature, sample movement/rotation, type of die, and atmosphere (gas type and pressure), the desired amorphous-crystalline composite structure is formed with enhanced thermoelectric properties. These variables depend on the material being processed and must be optimized to attain the desired structure. Those of ordinary skill in the art will realize that in some cases the optimization will need to be done by trial and error.

The concentration of the amorphous and crystalline domains can be adjusted to maximize the thermoelectric figure-of-merit and is not limited to small size domains.

An embodiment involves the development of fully amorphous, mixed amorphous-crystalline, and nano-crystalline thermoelectric (TE) material structures using microwave radiation. The method is applicable to any TE material that can absorb microwave energy. The absorption can be either through the electric field or the magnetic field of the microwave field. The microwave frequency can vary from 300 MHz to 300 GHz. The microwave field-material interaction can create non-equilibrium phases such as metastable or amorphous phases in the material structure. Creation of such material phases can enhance the TE performance, in particular, the TE dimensionless figure-of-merit (ZT), in comparison to the materials prepared with prevalent sintering methods.

Additive materials such as glass powder can be mixed with initial powders prior to consolidation to improve both the TE properties and mechanical behavior of the consolidated TE material against mechanical and/or thermal shocks and thermal cycling. The method is applicable to most TE materials such as, for example, nanostructured bulk Bi₂₋₂ₓSb₂ₓTe₃ (x=0.66 to 0.84) and Bi₂Sₑ₃ₓTe₃₋₃ₓ (x=0 to 0.34), magnesium silicide (Mg₂Si), higher manganese silicide (MnSi₁₊ₙ, n=0.73 to 0.75), and silicon germanium (Si₁₋ₓGeₓ, x=0 to 1), iron silicide (FeSi₂), cupper silicide, half-Heusler alloys, Skutterudites, clathrates, zintl phases, PbTe, zinc antimonide, oxide thermoelectrics, organic thermoelectrics, etc., based materials. The method is applicable to most consolidation approaches with or without microwave processing such as hot pressing, sintering in an oven without pressure, spark plasma sintering, plasma pressure compaction, etc.

Microwave energy has been widely used to synthesize and sinter different class of materials. However, the instant disclosure provides an extraordinary route to create a new state of amorphous, heterogeneous, and amorphous-crystalline composite materials in a rather quick and convenient way using microwave energy. The simple procedure and quick processing time of the method allows investigating and creating a large number of material structures with various dimensions. The present method proposed a scalable technique to produce high efficiency bulk TE structures as well as thin and thick films.

### Experimental

Various embodiments utilize a starting material in the form of a powder or bulk shape. Both alloyed powder and mixed of elemental powders can be used. The initial bulk sample can be in any shape. Any consolidation method such as hot pressing, cold pressing, cold press with subsequent sintering in an oven, spark plasma sintering and so on can be applied to densify the raw material. Moreover, a solidified ingot prepared from any melting method can also be used as the starting material.

FIG. 1 shows a schematic diagram of the invented microwave process with different exemplary configurations. The material being processed is inserted into a die. The die is made of a material, such as refractory materials, that can stand the processing temperature. The die is non-metallic to minimize the microwave reflection. Several examples include boron nitride, magnesium oxide, alumina, zirconia, silicon carbide, sapphire, aluminum nitride, titanium diboride, quartz, mullite, or a mixture of these materials with other elements. The die was put in a microwave transparent tube (e.g. quartz tube). The tube can be sealed, exposed to air, or be under a flowing gas. When sealed, the tube can be under vacuum or filled with controlling gas at various pressures. The microwave processing can be applied to thermoelectric rods of different sizes and densities. The experiment considered three different configurations: a static rod in static or dynamic atmosphere (FIG. 1A), a moving rod in static or dynamic atmosphere (FIG. 1B), a rod under pressure in static or dynamic atmosphere (FIG. 1C). The moving rod can be under tensile or compressive stress. In the dynamic atmosphere a gas is being purged during the process. The gas in the static or dynamic atmosphere can be inert, oxidizing, reducing, or a mixture of them. The static atmosphere can be vacuum or filled with gas.

The tube or the thermoelectric material can be subjected to axial or non-axial rotation and/or oscillation, i.e. displacement in any direction, in the cavity for uniform decrystallization and sintering.

The microwave power can be continuous or pulsed. The pulsed microwave power can be squared, sinusoidal, or any other shape with duty cycle of zero to one. The de-crystallization process happens by merely subjecting the material to the electric (E), magnetic (H) field, or a combination of E and H in the cavity at any temperature, i.e. below the glass transition temperature, below the melting point, at melting point, or above the melting temperature of the sample. The microwave frequency can be from 300 MHz to 300 GHz.

As a specific example, elemental powders of Si, Ge, B and glass were mixed together using planetary ball mill and hot pressed at 950 C. Microwave processing was performed on a consolidated rod (ρ<2.3 g/cm³) with a diameter of 6 mm and length of 18 mm. The hot-pressed sample was put in a BN die closed from the bottom side. On top of the sample, a movable BN rod and a push rod was used according to the FIG. 1A. The system was put and sealed inside a quartz tube under inert atmosphere. N₂ was used as controlling gas at the pressure of 720 torr. The sample in this particular example was rotated at approximately 20 rpm around the vertical axis inside the cavity.

The sample was processed in a custom made temperature controlled setup equipped with a pressing system. The quartz tube was inserted into the microwave cavity and the sample was gradually heated up with microwave radiation to a sub-melting temperature. The sample was held at sub-melting temperature for 5 minutes after which the microwave was turned off.

Electrical conductivity and Seebeck coefficient were measured by four probe method using the commercially available Ulvac, ZEM-3 instrument in the range of 28-990 C. The thermal conductivity of the samples was measured using laser flash instrument (Netzsch's LFA 457 Micro Flash).

### Results and Discussion

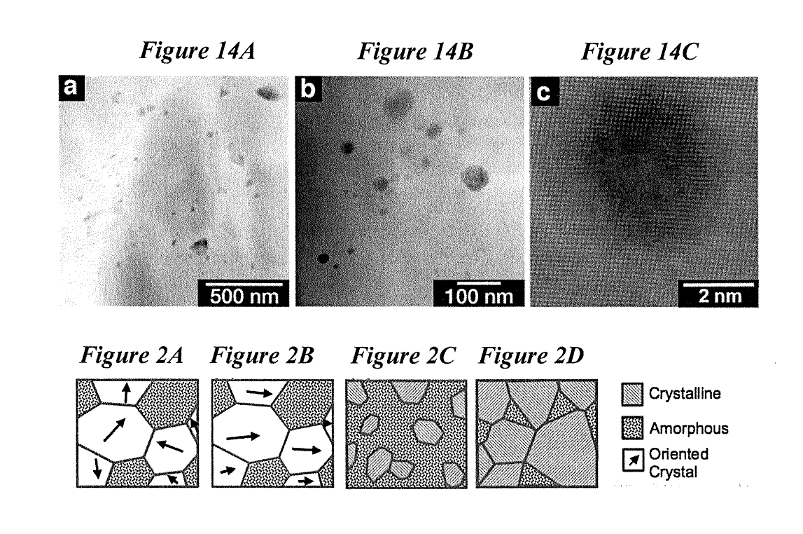

The microwave processing as described above can be used to develop new classes of materials structures based on bulk fully amorphous structures, amorphous-crystalline composites, heterogeneous structures, and nano-crystalline structures, and to control their TE properties. The amorphous-crystalline composite can contain mixed grains of amorphous and crystalline, crystalline host with mixed amorphous grains, or amorphous host containing crystalline grains (FIG. 2).

This method provides a route to creating amorphous, heterogeneous structures, and amorphous-crystalline materials in a rather quick and convenient way. The quick processing time of our method allows investigating a large number of TE materials.

The nanoscale effect in TE materials requires crystallite sizes smaller than a few ten nanometers, which is often difficult to reach in bulk structures using conventional sintering methods such as cold press with subsequent oven sintering, hot pressing, spark plasma sintering, or direct current heating. An obstacle is that during the sintering time, the grains grow and nanoscale features broaden or diminish during the process. Reducing the sintering time does not help either, as the material would not be properly sintered, which would result in low carrier mobility. Therefore, the sintered materials often have average crystallites larger than 20-30 nm in size at best. Therefore, a new synthesis method is highly desired to generate structures smaller crystallites to achieve high ZT. In this disclosure, it is demonstrated that the high electric, high magnetic, or a combination of electric and magnetic field in a microwave cavity can have sufficient energy to dislodge the atoms from their crystal lattice positions and decrystallize the material and result in good thermoelectric properties. The microwave processing can be performed below the melting temperature. The process is terminated with field quenching. The field quenching below the crystal growth temperature prevents the crystal growth after turning off the microwave energy.

Microwave processing can also provide textured decrystallized structures. Since the electric or magnetic field in the single mode microwave cavity is polarized, the decrystallization takes place at a plane normal to the field.

Microwave processing can provide preferential decrystallization of one or more number of phases or elements in compound, solid solution alloy, or a binary or multi-phase composite material.

Microwave processing can decompose components of an alloy. Decomposition can happen for solid-solution alloys. For example, Si and Ge can make a continuous solid solution with x=0 to 1. Upon microwave process Si_{0.8}Ge_{0.2} (x=0.2), during the microwave radiation, at first, different phases of Si₁₋ₓGeₓ (x=0 to 1) form a heterogeneous structure. If the microwave radiation continues, the material completely de-crystallizes and the final product will be a mixture of Si and Ge with 0.8:0.2 ratio.

The heterogeneous structure forms by microwave radiation of solid solution alloys AₓB₁₋ₓ where A and B are compounds, elements, or solid solution alloys themselves, such as (Bi₂Te₃)_{y}(Sb₂Te₃)_{z}(Bi₂₋₂ₓSb₂ₓTe₃)_{1-y-z} with x, y, z each changing from 0 to 1 or Si₁₋ₓGeₓ with x=0 to 1.

A heterogeneous phase can improve the thermoelectric properties by improving the thermoelectric power factor and/or reducing the thermal conductivity.

It is also possible to make nanocomposites consisting of mixed phases of crystalline and amorphous domains using the microwave processing. Such structures can show different properties than the crystalline or amorphous phases. For example, experimental data shows that the synthesized amorphous-crystalline silicon germanium has a very high electrical conductivity. Here, the thermal conductivity was reduced while simultaneously increasing the thermoelectric power factor, which is often difficult to achieve. For p-type SiGeB, ZT≈1.9 at T≈990 C was achieved with this method which is near 100% improvement in comparison to the highest reported ZT values for this material and 280% higher than the conventional SiGe used in NASA space-crafts.

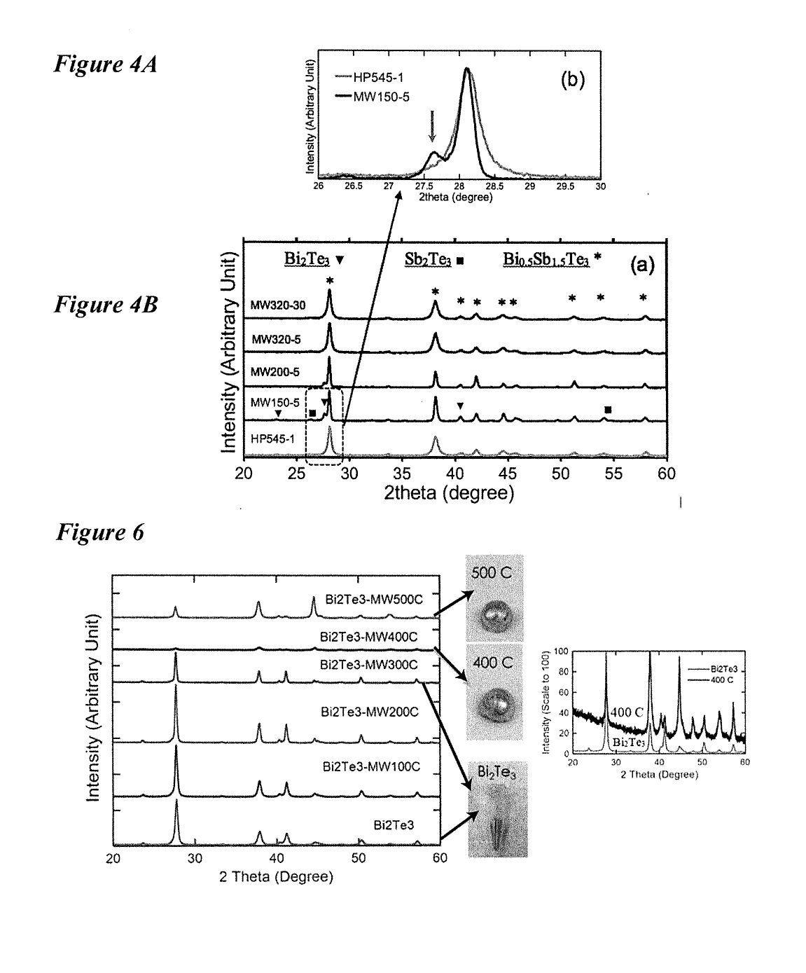

In another example, an embodiment of the microwave process disclosed herein was applied to Bi_{0.5}Sb_{1.5}Te₃ alloy in order to reduce its thermal conductivity. As a result, a high density of defects and decrystallization was introduced in the structure which resulted in ˜15% reduction of the thermal conductivity. FIG. 4A shows the comparison of the XRD patterns for the hot pressed sample (HP545-1) and the same sample which, after the hot press, was subsequently microwave processed at 150 C for 5 min (MW150-5), 200 C for 5 min (MW200-5), 320 C for 5 min (MW320-5) and 320 C for 30 min (MW320-30). XRD patterns of MW150-5 and MW200-5 are similar and show decomposed phases of Bi₂Te₃ and Sb₂Te₃. However, further increasing the process temperature and time resulted in the formation of uniform Bi_{0.5}Sb_{1.5}Te₃ alloy similar to the starting hot pressed sample.

The comparison of higher resolution XRD pattern in the range of 2θ=26-30° for MW200-5 and MW320-5 (FIG. 4B) indicates phase decomposition in the sample MW200-5. This pattern indicates that MW process can decrystallize BiSbTe alloy to a heterogeneous structure consisting of Bi₂Te₃ and Sb₂Te₃ phases that can potentially decrease the thermal conductivity. This composite structure can contain a mixture of many phases such as (Bi₂Te₃)_{y}(Sb₂Te₃)_{z}(Bi₂₋₂ₓSb₂ₓTe₃)_{1-y-z} with x, y, z each changing from 0 to 1.

FIG. 5A illustrates the thermal diffusivity of the microwave processed materials in comparison with their initial hot press sample. In MW-processed samples the thermal diffusivity reduces up to a certain temperature, then, it increases by either temperature or time. The lowest thermal diffusivity was achieved in the sample MW200-5 which is ˜0.5 m²/s.

FIG. 5B shows the thermal conductivity data of the MW processed samples compared with the hot-pressed sample. In comparison to HP540-1, all MW samples show lower thermal conductivity at room temperature. This value for MW200-5 is ˜0.6 W/mK which is ˜15% less than the initial hot-pressed value.

A similar study on the effect of microwave process temperature on decrystallization of Bi₂Te₃ powder showed interesting results. FIG. 6 shows the comparison of XRD patterns of microwave processed Bi₂Te₃ powders at 100, 200, 300, 400 and 500 C. The XRD of the starting Bi₂Te₃ powder is also shown for comparison. The decrystallization rate increases with process temperature up to 400 C. At this temperature, the powder melted and the decrystallization was maximum. Continuing the process up to 500 C resulted in reducing the decrystallized phase and texturing of the material as indicated by the change in the relative intensities of the XRD peaks.

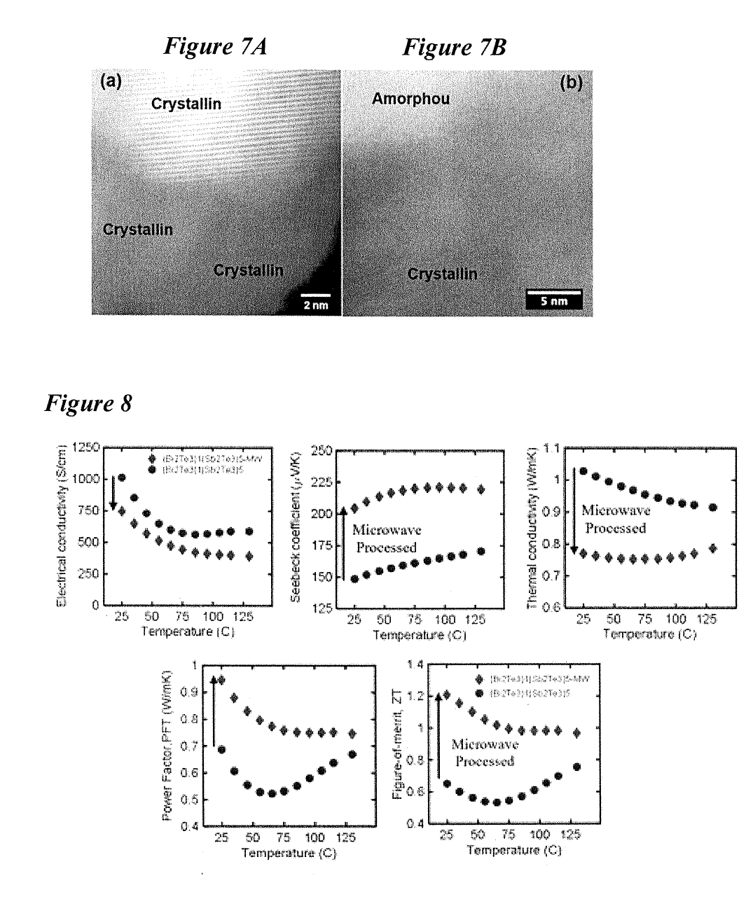

FIG. 7 compares the transmission electron microscopy (TEM) images of as-prepared Bi₂Te₃ (FIG. 7A) powder and microwave processed Bi₂Te₃ (FIG. 7B). As is shown in the XRD patterns (FIG. 6), the microwave processed sample consists of amorphous and crystalline phases. The TEM image also confirms this mixed amorphous-crystalline structure.

The effect of microwave processing on p-type hot-pressed (Bi₂Te₃)₁(Sb₂Te₃)₅ samples is illustrated in FIG. 8. The comparison of two different samples before and after microwave processing shows that microwave process improves ZT while decreasing the thermal conductivity. This p-type material was used to develop exemplary thermoelectric devices that are several times more efficient than commercial devices as shown in FIG. 10. The device was fabricated from microwave processed p-type and commercial n-type legs. The fabrication process follows the standard steps used in industry for the packaging of the thermoelectric devices.

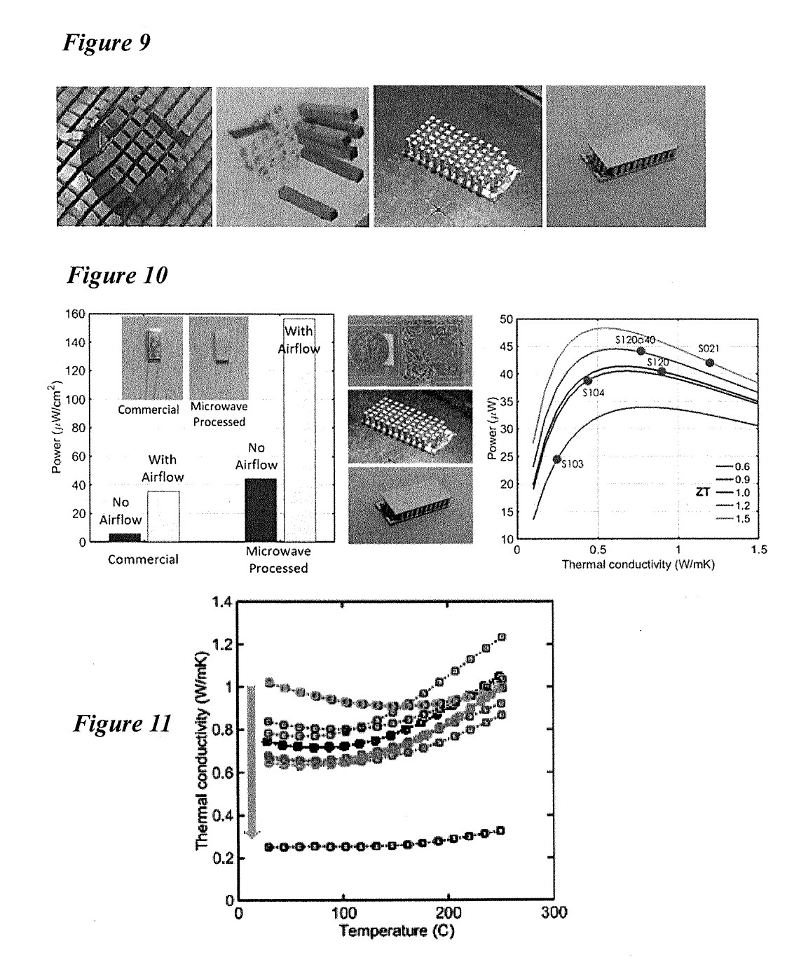

In order to evaluate the competitiveness of materials produced by an embodiment with existing commercial thermoelectric devices, thermoelectric generator (TEG) devices were fabricated out of materials produced as described herein and then benchmarked against the best available commercial TEG from Marlow Industries. For this purpose, TE legs with size of 0.6 mm×0.6 mm×2 mm were cut and prepared for packaging into a TEG device (FIG. 9). The TEG devices were measured in terms of the output power and voltage and compared with the results from commercial TE devices. Both devices were tested under similar conditions sitting on a 2 mm thick PDMS on a hot plate at 37 C. The commercial device produced 3.3 mV/cm² and 0.24 μW/cm², and the microwave processed device produced 11.4 mV/cm² and 1.0 μW/cm².

The instant example device produced 3.45 times more voltage and 4.2 times more power as compared with one of the best commercial TE devices. Neither a heat spreader nor a heat sink was used for this test. It is expected that the TEG will generate higher power with a heat spreader and/or a heat sink.

The microwave processed TEG was further measured on body and the produced power by that of a commercial device was measured. FIG. 10 contains the results of this comparison.

The microwave processed TEG produced 4-7 times more power compared with a commercial TEG of similar area under similar condition on body. The produced power was a function of the airflow as expected. The airflow reduces the cold side temperature, which increases the temperature difference across the TEG; hence, the electrical power. Under no air flow condition the microwave processed device produced 44 μW/cm² and the commercial device produced 5.7 μW/cm². With airflow, the microwave processed produced 156.5 μW/cm² and the commercial device produced 35.5 μW/cm². The data is plotted in FIG. 9 for comparison.

This is the highest power generation reported from body heat and offers broad range of commercial application such as self-powered wearable electronic devices. It should be noted that since the microwave de-crystallization process does not require melting of the material, the process can be scaled up for large size material processing and is appropriate for commercialization.

FIG. 11 shows an example of the thermal conductivity data of the microwave processed p-type BiSbTe alloys compared with the hot-pressed sample (Cyan Square). In comparison to hot press sample, all microwave processed samples in this example show lower thermal conductivity at room temperature. This value is ˜0.25 W/mK which is lowest thermal conductivity reported for this alloy.

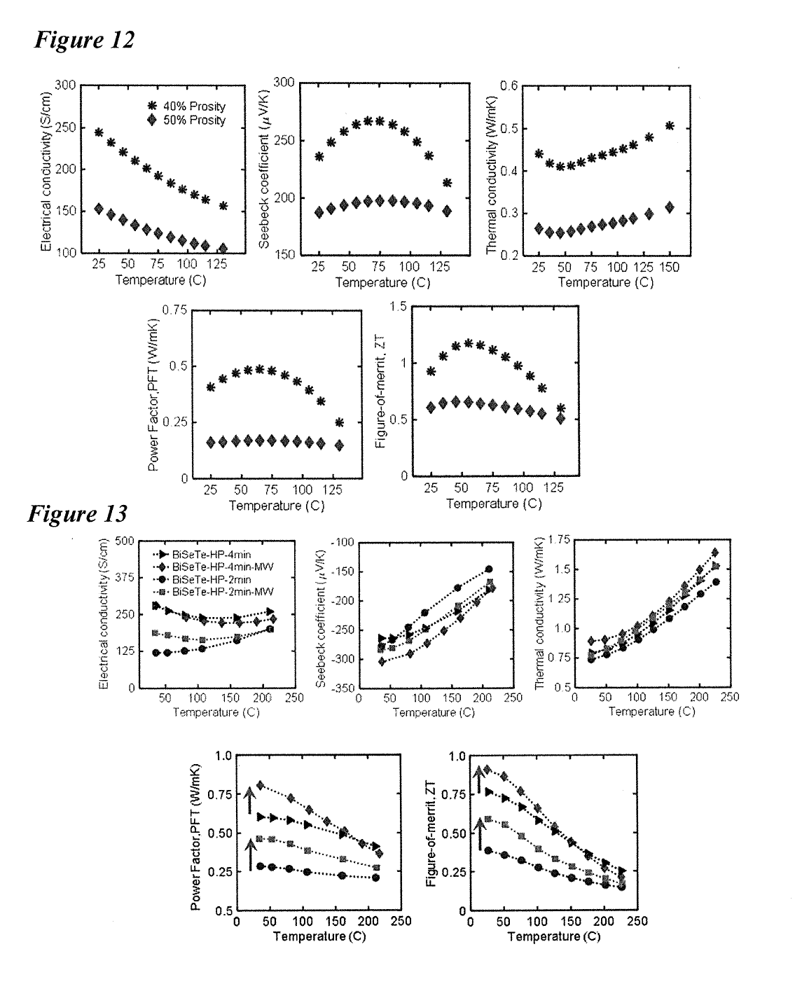

Another capability of the microwave processing is to control the porosity of the samples, i.e. reducing the density. The porosity happens during the microwave radiation above a certain temperature and pressure, which depends on the material properties. The method can be very useful in reduction of thermal conductivity. For example, a Bi_{0.5}Sb_{1.5}Te₃ sample with 50% porosity showed thermal conductivity of ˜0.25 W/mK at room temperature (FIG. 12).

In another example, the effect of microwave processing on n-type hot-pressed BiSeTe samples was studied. FIG. 13 illustrates the comparison of two different samples before and after microwave processing according to an embodiment. The microwave processing improved the thermoelectric properties of n-type BiSeTe.

FIG. 14 contains example TEM images of the microwave processed n-type BiSeTe sample. The sample contains ˜500 nm BiSeTe grains with dark regions which are extended throughout the grains in the entire sample (FIGS. 14A and 14B). Atomic resolution image of the dark demonstrates a highly disordered region surrounded by the bulk of the crystalline grain (FIG. 14C). The size of disordered/crystalline regions result in improved thermoelectric properties by reducing the thermal conductivity and enhancing Seebeck coefficient.

Many TE materials can be sintered and/or de-crystalized with the discussed microwave processing approach. Materials in the shape of powder, cold pressed, hot pressed, and solidified from the melt, single crystalline, polycrystalline, nanocrystalline, or nanocomposites can be processed via various embodiments. The material composition can be single element, mixed element, or alloyed compound. The microwave system can be applied to mixed powder or pressed form of several elements to simultaneously sinter, de-crystallize, and form the alloy or mixture of one or more alloys and elements.

The sequence of sintering, such as hot pressing, followed by microwave processing can be repeated twice or several times to improve the materials mechanical and thermoelectric properties.

Such capabilities open a new landscape for discovering new electronic amorphous based structures. This process can readily be scaled up for large size material processing by those of ordinary skill in the art.

### (b) Use of Additive Materials Prior to Microwave Sintering for Improving the Mechanical and Thermoelectric Properties of Materials

Glass inclusions in the thermoelectric materials have the potential to improve the end result mechanical properties, e.g., the stability against mechanical and/or thermal shocks or thermal cycling, and reduced the cracks. The glass inclusion also may improve the electrical conductivity by reducing the micro-cracks in the material. The method is potentially especially useful in polycrystalline and nanostructured bulk TE materials.

Nanostructured bulk Bi₂₋₂ₓSb₂ₓTe₃ and Bi₂Se₃ₓTe₃₋₃ₓ, even though they may have higher ZT than their crystalline form, typically suffer from poor electrical contact when used in a TE module due to the formation of parallel cracks to the metal pads at the contact area. The addition of a glass material can prevent crack formation and enhance the mechanical properties of the material. For this purpose, the glass powder was mixed with the TE powder prior to consolidation and the mixed powder was sintered.

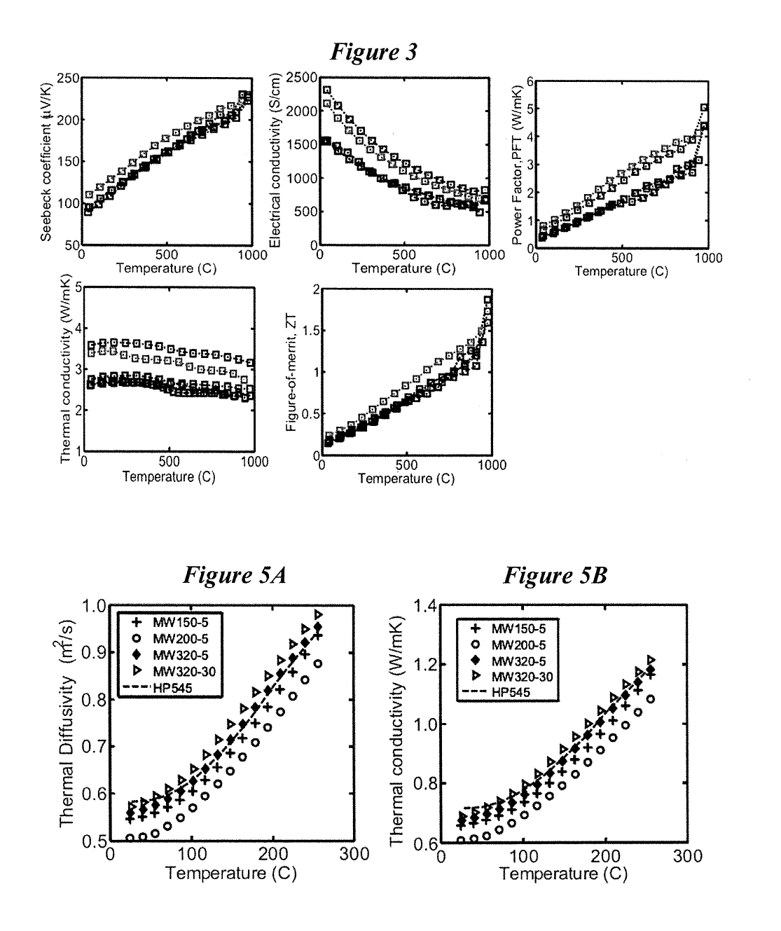

As another example, powders of Si, Ge and B were mixed with an appropriate amount of glass using planetary ball mill. Different percentages of the glass were added to the initial mixture of the powders to control the process and to reduce the sintering temperature. This powder was sintered using the microwave technique described before in this application. The microwave sintering reduced the optimum mechanical milling time prior to sintering. The microwave processed rod was a dense structure without cracks and with good mechanical properties. The TE properties of the microwave processed samples showed a ZT≈1.9 at 990 C for p-type SiGe alloy, which was 100% enhancement in comparison to the highest reported ZT for p type SiGe. Another achievement in these samples is ZT≈1 at 600 C for p-type SiGe which candidates this material for application at lower temperatures (FIG. 3).

### CONCLUSIONS

Embodiments of the technique herein include:

Microwave sintering in a single mode cavity provides a new method to prepare fully amorphous or amorphous-crystalline composites with superior TE properties. The method can be equally applied to thin films or bulk materials. For the first time, the amorphous-crystalline bulk structure was developed for p-type silicon germanium TE materials with ZT˜1.9 at 990 C. This method can be applied to other TE or electronic materials.

Additionally, embodiments show that the addition of a glass to the microwave processed TE material can increase both electrical and mechanical properties by reducing the micro-cracks and pores in the material.

It is to be understood that the terms “including”, “comprising”, “consisting” and grammatical variants thereof do not preclude the addition of one or more components, features, steps, or integers or groups thereof and that the terms are to be construed as specifying components, features, steps or integers.

If the specification or claims refer to “an additional” element, that does not preclude there being more than one of the additional element.

It is to be understood that where the claims or specification refer to “a” or “an” element, such reference is not be construed that there is only one of that element. It is to be understood that where the specification states that a component, feature, structure, or characteristic “may”, “might”, “can” or “could” be included, that particular component, feature, structure, or characteristic is not required to be included.

Where applicable, although state diagrams, flow diagrams or both may be used to describe embodiments, the invention is not limited to those diagrams or to the corresponding descriptions. For example, flow need not move through each illustrated box or state, or in exactly the same order as illustrated and described.

Methods of the present invention may be implemented by performing or completing manually, automatically, or a combination thereof, selected steps or tasks.

The term “method” may refer to manners, means, techniques and procedures for accomplishing a given task including, but not limited to, those manners, means, techniques and procedures either known to, or readily developed from known manners, means, techniques and procedures by practitioners of the art to which the invention belongs.

For purposes of the instant disclosure, the term “at least” followed by a number is used herein to denote the start of a range beginning with that number (which may be a ranger having an upper limit or no upper limit, depending on the variable being defined). For example, “at least 1” means 1 or more than 1. The term “at most” followed by a number is used herein to denote the end of a range ending with that number (which may be a range having 1 or 0 as its lower limit, or a range having no lower limit, depending upon the variable being defined). For example, “at most 4” means 4 or less than 4, and “at most 40%” means 40% or less than 40%. Terms of approximation (e.g., “about”, “substantially”, “approximately”, etc.) should be interpreted according to their ordinary and customary meanings as used in the associated art unless indicated otherwise. Absent a specific definition and absent ordinary and customary usage in the associated art, such terms should be interpreted to be ±10% of the base value.

When, in this document, a range is given as “(a first number) to (a second number)” or “(a first number)−(a second number)”, this means a range whose lower limit is the first number and whose upper limit is the second number. For example, 25 to 100 should be interpreted to mean a range whose lower limit is 25 and whose upper limit is 100. Additionally, it should be noted that where a range is given, every possible subrange or interval within that range is also specifically intended unless the context indicates to the contrary. For example, if the specification indicates a range of 25 to 100 such range is also intended to include subranges such as 26-100, 27-100, etc., 25-99, 25-98, etc., as well as any other possible combination of lower and upper values within the stated range, e.g., 33-47, 60-97, 41-45, 28-96, etc. Note that integer range values have been used in this paragraph for purposes of illustration only and decimal and fractional values (e.g., 46.7-91.3) should also be understood to be intended as possible subrange endpoints unless specifically excluded.

It should be noted that where reference is made herein to a method comprising two or more defined steps, the defined steps can be carried out in any order or simultaneously (except where context excludes that possibility), and the method can also include one or more other steps which are carried out before any of the defined steps, between two of the defined steps, or after all of the defined steps (except where context excludes that possibility).

Further, it should be noted that terms of approximation (e.g., “about”, “substantially”, “approximately”, etc.) are to be interpreted according to their ordinary and customary meanings as used in the associated art unless indicated otherwise herein. Absent a specific definition within this disclosure, and absent ordinary and customary usage in the associated art, such terms should be interpreted to be plus or minus 10% of the base value.

Still further, additional aspects of the instant invention may be found in one or more appendices attached hereto and/or filed herewith, the disclosures of which are incorporated herein by reference as if fully set out at this point.

Thus, the present invention is well adapted to carry out the objects and attain the ends and advantages mentioned above as well as those inherent therein. While the inventive device has been described and illustrated herein by reference to certain preferred embodiments in relation to the drawings attached thereto, various changes and further modifications, apart from those shown or suggested herein, may be made therein by those of ordinary skill in the art, without departing from the spirit of the inventive concept the scope of which is to be determined by the following claims.

1. A method of producing an amorphous or amorphous-crystalline material, comprising the steps of:
a. obtaining a quantity of a thermoelectric material;
b. configuring a microwave cavity to produce a standing wave when radiated by microwave radiation;
c. activating a microwave generator to produce said microwave radiation and said standing wave;
d. exposing the thermoelectric material to said standing wave for a length of time at least long enough to produce said amorphous or amorphous-crystalline material.

2. A method according to claim 1, wherein said microwave generator operates at a frequency between 300 MHz and 300 Ghz.

3. A method according to claim 1, wherein said thermoelectric material further comprises an amount of glass therein.

4. A method according to claim 1, wherein said thermoelectric material is selected from the group consisting of Bi₂₋₂ₓSb₂ₓ, Te₃ (x=0.66 to 0.84), Bi₂Se₃ₓTe₃₋₃ₓ (x=0.66 to 0.84), magnesium silicide (Mg₂Si), higher manganese silicide (MnSi₁₊ₙ, n=0.73 to 0.75), silicon, silicon germanium (Si₁₋ₓGeₓ, x=0 to 1), iron silicide (FeSi₂), copper silicide, half-Heusler alloys, Skutterudites, clathrates, zintl phases, PbTe, zinc antimonide, oxide thermoelectrics, and organic thermoelectrics.

5. A method according to claim 3, wherein said amount of glass is selected from the group consisting of a Si glass, a Ge glass, and a B glass.

6. A method according to claim 1, wherein said thermoelectric material is rotated for at least a portion of the length of time it is exposed to said standing microwave signal.

7. A method according to claim 1, wherein said standing wave signal has a voltage standing wave ratio between 1.0 and 2.0.

8. A method according to claim 1, wherein said length of time at least long enough to produce said amorphous or amorphous-crystalline material is between a few seconds and a few hours.

9. A method according to claim 1, wherein said thermoelectric material is in a powder form, a bulk form or a thin film form.

10. A device for creating an amorphous or amorphous-crystalline material from a thermoelectric material, comprising:
a. a microwave generator operable to produce a microwave signal;
b. a reflective partition, said reflective partition configured to reflect at least a portion of said microwave signal back toward said microwave generator;
c. a microwave cavity situated between said microwave generator and said reflective partition;
d. a sample container within said microwave cavity, said sample container configurable to house said thermoelectric material;
e. an isolator situated between said microwave cavity and said microwave generator; and,
f. a tuner situated between said isolator and said generator, said tuner adaptable to match a load created by said sample container to said microwave signal, said tuner and said partition operable together to creating a standing wave signal within said microwave cavity when said microwave generator is operating.

11. A device according to claim 10, wherein said sample container comprises
1. a microwave transparent housing, and,
2. a nonmetallic die within said microwave transparent housing, said die containing said thermoelectric material.

12. A device according to claim 11, wherein said nonmetallic die is made of a material selected from the group consisting of boron nitride, magnesium oxide, alumina, zirconia, silicon carbide, sapphire, aluminum nitride, titanium diboride, quartz, and mullite.

13. A device according to claim 11, wherein said microwave transparent housing is made of quartz.

14. A device according to claim 10, wherein said reflective partition is movable.

15. A device according to claim 10, wherein said reflective partition is a plunger.

16. A device according to claim 10, wherein said tuner is a three-stub tuner or an E-H tuner.

17. A method of producing a heterogeneous phase material, comprising the steps of:
a. obtaining a quantity of a thermoelectric material;
b. configuring a microwave cavity to produce a standing wave when radiated by microwave radiation;
c. activating a microwave generator to produce said microwave radiation and said standing wave;
d. exposing the thermoelectric material to said standing wave for a length of time at least long enough to produce said heterogeneous phase material.

18. A method according to claim 17, further comprising the step of:
e. exposing the thermoelectric material to said standing wave for an additional length of time at least long enough to produce an amorphous or amorphous-crystalize material.

19. A method according to claim 17, wherein said thermoelectric material is Si_{0.8}Ge_{0.2} and said heterogeneous phase material is Si₁₋ₓGeₓ with x varying between 0 and 1.

20. A method according to claim 17, wherein said thermoelectric material is Bi_{0.5}Sb_{1.5}Te₃ and said heterogeneous phase material is (Bi₂Te₃)_{y}(Sb₂Te₃)_{z}(Bi₂₋₂ₓSb₂ₓTe₃)_{1-y-z} with x, y, z each varying between 0 and 1.

21. A method according to claim 18, wherein said thermoelectric material is a solid solution alloy A₁₋ₓ₀Bₓ₀ with a fixed x₀ and said heterogeneous phase material comprises A₁₋ₓBₓ with x varying between 0 and 1, wherein A and B are compounds or elemental materials.
